(19) United States
(12) Patent Application Publication
(10) Pub. No.: US 2014/0029359 A1
(43) Pub. Date: Jan. 30, 2014

(54) SENSE AMPLIFIER CIRCUIT AND MEMORY DEVICE INCLUDING THE SAME

(71) Applicant: SK HYNIX INC., Gyeonggi-do (KR)

(72) Inventor: Hyung-Soo KIM, Gyeonggi-do (KR)

(73) Assignee: SK hynix Inc., Gyeonggi-do (KR)

(21) Appl. No.: 13/717,269

(22) Filed: Dec. 17, 2012

(30) Foreign Application Priority Data
Jul. 30, 2012 (KR) 10-2012-0083009

(51) Int. Cl. G11C 7/06; H03F 3/16; G11C 7/12

(52) U.S. Cl. CPC G11C 7/06; G11C 7/12; H03F 3/16
USPC 365/189.11; 330/277

(57) ABSTRACT

A sense amplifier circuit includes a first pull-up transistor configured to pull-up drive a data bar line in response to a voltage of a data line, a first pull-down transistor configured to pull-down drive the data bar line in response to the voltage of the data line, and to receive the voltage of the data line through a back gate of the first pull-down transistor, a second pull-up transistor configured to pull-up drive the data line in response to a voltage of the data bar line, and a second pull-down transistor configured to pull-down drive the data line in response to the voltage of the data bar line, and to receive the voltage of the data bar line through a back gate of the second pull-down transistor.

### CROSS-REFERENCE TO RELATED APPLICATIONS

The present application claims priority of Korean Patent Application No. 10-2012-0083009, filed on Jul. 30, 2012, which is incorporated herein by reference in its entirety.

### BACKGROUND

1. Field

Exemplary embodiments of the present invention relate to a sense amplifier circuit and a memory device including the same.

2. Description of the Related Art

Memory devices and various integrated circuits mainly use a sense amplifier circuit for sensing data. The sense amplifier circuit senses data having a small voltage difference between a logic ‘high’ level and a logic ‘low’ level, that is, data for which determination of a logic level is difficult.

FIG. 1 is a configuration diagram illustrating a sense amplifier circuit used in a conventional memory device.

Referring to FIG. 1, the sense amplifier circuit includes two PMOS transistors P1 and P2 and two NMOS transistors N1 and N2.

When data is read from a memory cell (not illustrated) in a cell array, a voltage level of a bit line BLT or a bit bar line BLB changes. Since the change in the voltage level of the bit line BLT or the bit bar line BLB due to the data of the memory cell is very small, the voltage level of the bit line pair BLT and BLB is amplified through the sense amplifier circuit. The operation of the sense amplifier circuit will be described. When the voltage level of the bit line BLT is higher than the voltage level of the bit bar line BLB, the PMOS transistor P1 and the NMOS transistor N2 are strongly turned on compared to the PMOS transistor P2 and the NMOS transistor N1, so that the voltage level of the bit line BLT is a level of a pull-up voltage terminal RTO, and the voltage level of the bit bar line BLB is a level of a pull-down voltage terminal SB. Furthermore, when the voltage level of the bit bar line BLB is higher than the voltage level of the bit line BLT, the PMOS transistor P2 and the NMOS transistor N1 are strongly turned on compared to the PMOS transistor P1 and the NMOS transistor N2, so that the voltage level of the bit bar line BLB is the level of the pull-up voltage terminal RTO, and the voltage level of the bit line BLT is the level of the pull-down voltage terminal SB.

In order for the sense amplifier circuit to accurately sense and amplify data loaded on the bit line pair, mismatch should not exist among the transistors P1, P2, N1, and N2 constituting the sense amplifier circuit. However, as a delicate fabrication process of an integrated circuit is performed, the possibility of mismatch between the NMOS transistors increases. Particularly, the mismatch and the threshold voltage difference between the NMOS transistors become larger, so that accurate data sensing of the sense amplifier circuit becomes difficult.

FIG. 2 is a diagram illustrating the operation of the sense amplifier circuit of FIG. 1.

Referring to FIG. 2, at a time point ‘201’, the bit line BLT and the bit bar line BLB have been precharged with substantially the same voltage (a precharge voltage: VBLP). At a time point ‘202’, when data is loaded on the bit line BLT, the voltage level of the bit line BLT is higher than the voltage level of the bit bar line BLB by dV. At a time point ‘203’, power is supplied to the pull-up voltage terminal RTO and the pull-down voltage terminal SB of the sense amplifier circuit, so that the pull-up voltage terminal RTO has a level of a pull-up voltage (in general, a power supply voltage) and the pull-down voltage terminal SB has a level of a pull-down voltage (in general, a ground voltage). Furthermore, from the time point ‘203’ at which the power is supplied to the pull-up voltage terminal RTO and the pull-down voltage terminal SB, a sense amplification operation of the sense amplifier circuit is started.

(a) of FIG. 2 illustrates the operation of the sense amplifier circuit when the mismatch between the NMOS transistors N1 and N2 is smaller than dV. Referring to (a) of FIG. 2, the voltage level of the bit line BLT is amplified to a high level (a pull-up voltage level) and the voltage level of the bit bar line BLB is amplified to a low level (a pull-down voltage level) by the sense amplifier circuit.

(b) of FIG. 2 illustrates the operation of the sense amplifier circuit when the mismatch between the NMOS transistors N1 and N2 is larger than dV, Referring to (b) of FIG. 2, the voltage level of the bit bar line BLB is erroneously recognized to be higher than the voltage level of the bit line BLT due to mismatch between the NMOS transistors N1 and N2, so that the bit line is amplified to a low level (a pull-down voltage level) and the bit bar line is amplified to a high level (a pull-up voltage level).

The abnormal operation as illustrated in (b) of FIG. 2 may occur because threshold voltages of the NMOS transistors are different from each other due to the mismatch between the NMOS transistors. For example, when the threshold voltage of the NMOS transistor N2 is higher than the threshold voltage of the NMOS transistor N1, the concern as illustrated in (a) of FIG. 2 may occur.

### SUMMARY

An embodiment of the present invention is directed to alleviate a concern that a sense amplifier circuit erroneously recognizes data.

In accordance with an embodiment of the present invention, a sense amplifier circuit may include a first pull-up transistor configured to pull-up drive a data bar line in response to a voltage of a data line, a first pull-down transistor configured to pull-down drive the data bar line in response to the voltage of the data line, and to receive the voltage of the data line through a back gate of the first pull-down transistor, a second pull-up transistor configured to pull-up drive the data line in response to a voltage of the data bar line, and a second pull-down transistor configured to pull-down drive the data line in response to the voltage of the data bar line, and to receive the voltage of the data bar line through a back gate of the second pull-down transistor. Each of the first pull-down transistor and the second pull-down transistor may include a fully depleted silicon on insulator (FDSOI) NMOS transistor.

In accordance with another embodiment of the present invention, a memory device may include one or more cell arrays, a bit line and a bit bar line connected to the one or more cell arrays, a first pull-up transistor configured to pull-up drive the bit bar line in response to a voltage of the bit line, a first pull-down transistor configured to pull-down drive the bit bar line in response to the voltage of the bit line, and to receive the voltage of the bit line through a back gate of the first pull-down transistor, a second pull-up transistor configured to pull-up drive the bit line in response to a voltage of the bit bar line, and a second pull-down transistor configured to pull-down drive the bit line in response to the voltage of the bit bar line, and to receive the voltage of the bit bar line through a back gate of the second pull-down transistor. Each of the first pull-down transistor and the second pull-down transistor may include a fully depleted silicon on insulator (FDSOI) NMOS transistor.

According to the embodiments of the present invention, threshold voltages of transistors including a sense amplifier circuit are changed to be suitable for data sensing. Consequently, data recognition failure of the sense amplifier circuit may be prevented.

### BRIEF DESCRIPTION OF THE DRAWINGS

FIG. 1 is a configuration diagram illustrating a sense amplifier circuit used in a conventional memory device.

FIG. 2 is a diagram illustrating the operation of a sense amplifier circuit of FIG. 1.

FIG. 3 is a configuration diagram illustrating a memory device in accordance with an embodiment of the present invention.

FIG. 4 is a diagram illustrating a change in threshold voltages according to back gate voltages of pull-down transistors N31 and N32.

FIG. 5 is a diagram illustrating data sensing pass/fail areas of a conventional sense amplifier circuit (FIG. 1) and a sense amplifier circuit 320 according to the embodiment of the present invention.

FIG. 6 is a configuration diagram illustrating a memory device in accordance with another embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention. In this specification, ‘connected/coupled’ represents that one component is directly coupled to another component or indirectly coupled through another component. In addition, a singular form may include a plural form as long as it is not specifically mentioned in a sentence.

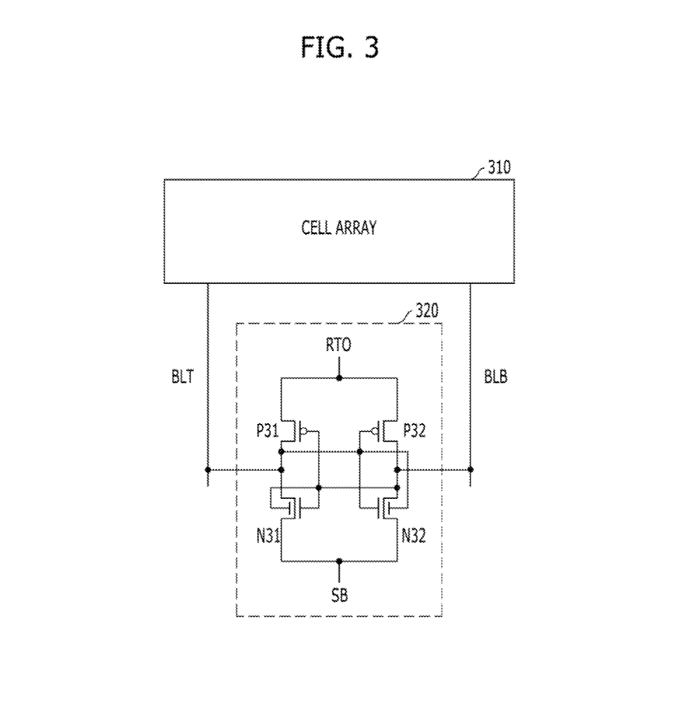

FIG. 3 is a configuration diagram illustrating a memory device in accordance with an embodiment of the present invention.

Referring to FIG. 3, the memory device includes a cell array 310, bit lines BLT and BLB, and a sense amplifier circuit 320.

The cell array 310 includes a plurality of memory cells in which a plurality of rows and a plurality of columns are arranged, wherein each memory cell is configured to store data. The bit lines BLT and BLB transfer data stored in the memory cells in the cell array. FIG. 3 illustrates only one bit line pair of BLT and BLB. However, a plurality of bit line pairs may exist in the cell array.

The sense amplifier circuit 320 is configured to amplify a voltage difference between a bit line BLT and a bit bar line BLB and to recognize data. The sense amplifier circuit 320 includes pull-up transistors P31 and P32 and pull-down transistors N31 and N32.

The pull-up transistor P32 is configured to pull-up drive the bit bar line BLB in response to a voltage of the bit line BLT. The pull-up transistor P31 is configured to pull-up drive the bit line BLT in response to a voltage of the bit bar line BLB. The pull-up transistors P31 and P32 may include PMOS transistors.

The pull-down transistor N32 is configured to pull-down drive the bit bar line BLB in response to the voltage of the bit line BLT. The pull-down transistor N32 includes a fully depleted silicon on insulator (FDSOI) NMOS transistor, and receives the voltage of the bit line BLT through a back gate thereof. The pull-down transistor N31 is configured to pull-down drive the bit line BLT in response to the voltage of the bit bar line BLB. The pull-down transistor N31 includes a FDSOI NMOS transistor, and receives the voltage of the bit bar line BLB through a back gate thereof.

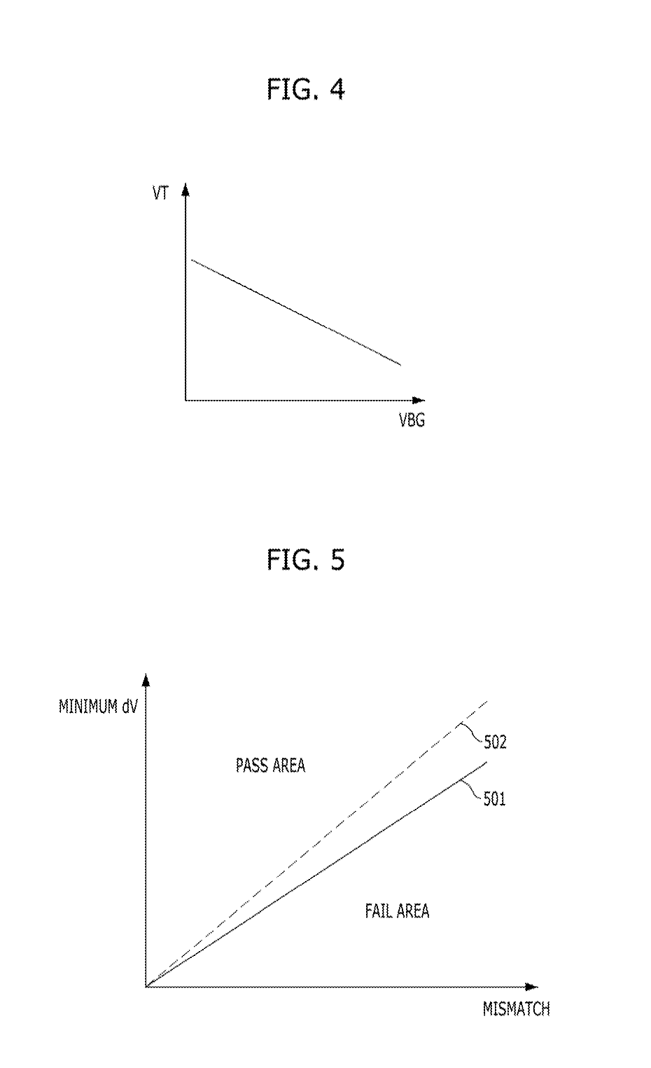

Threshold voltages of the pull-down transistors N31 and N32 including the FDSOI NMOS transistor are changed based on the level of the voltage supplied to the back gates thereof, and the sense amplifier circuit 320 of the embodiment of the present invention uses such characteristics. This will be described in more detail with reference to FIG. 4.

FIG. 4 is a diagram illustrating a change in the threshold voltages based on the back gate voltages of the pull-down transistors N31 and N32.

Referring to FIG. 4, as the back gate voltages VBG of the pull down transistors N31 and N32 including the FDSOI NMOS are increased, the threshold voltage VT is reduced. Due to such characteristics, a data sensing operation of the sense amplifier circuit 320 may become more accurate, which will be described according to data patterns.

First, when the voltage level of the bit line BLT is higher than the voltage level of the bit bar line BLB, the sense amplifier circuit 320 correctly recognizes data when the pull-down transistor N32 and the pull-up transistor P31 are turned on, and the pull-down transistor N31 and the pull-up transistor P32 are turned off. Since the pull-down transistors N31 and N32 include the FDSOI NMOS, the threshold voltage of the pull-down transistor N32 is reduced and the threshold voltage of the pull-down transistor N31 is increased due to the characteristics of the FDSOI NMOS. Accordingly, the pull-down transistor N32 is easily turned on and the pull-down transistor N31 is not easily turned on. That is, the threshold voltage characteristics of the pull-down transistors N31 and N32 are changed to be more suitable for data sensing.

Second, when the voltage level of the bit bar line BLB is higher than the voltage level of the bit line BLT, the sense amplifier circuit 320 correctly recognizes data when the pull-down transistor N31 and the pull-up transistor P32 are turned on, and the pull-down transistor N32 and the pull-up transistor P31 are turned off. Due to the characteristics of the FDSOI NMOS, the threshold voltage of the pull-down transistor N31 is reduced and the threshold voltage of the pull-down transistor N32 is increased. Accordingly, the pull-down transistor N31 is easily turned on and the pull-down transistor N32 is not easily turned on. That is, the threshold voltage characteristics of the pull-down transistors N31 and N32 are changed to be more suitable for data sensing.

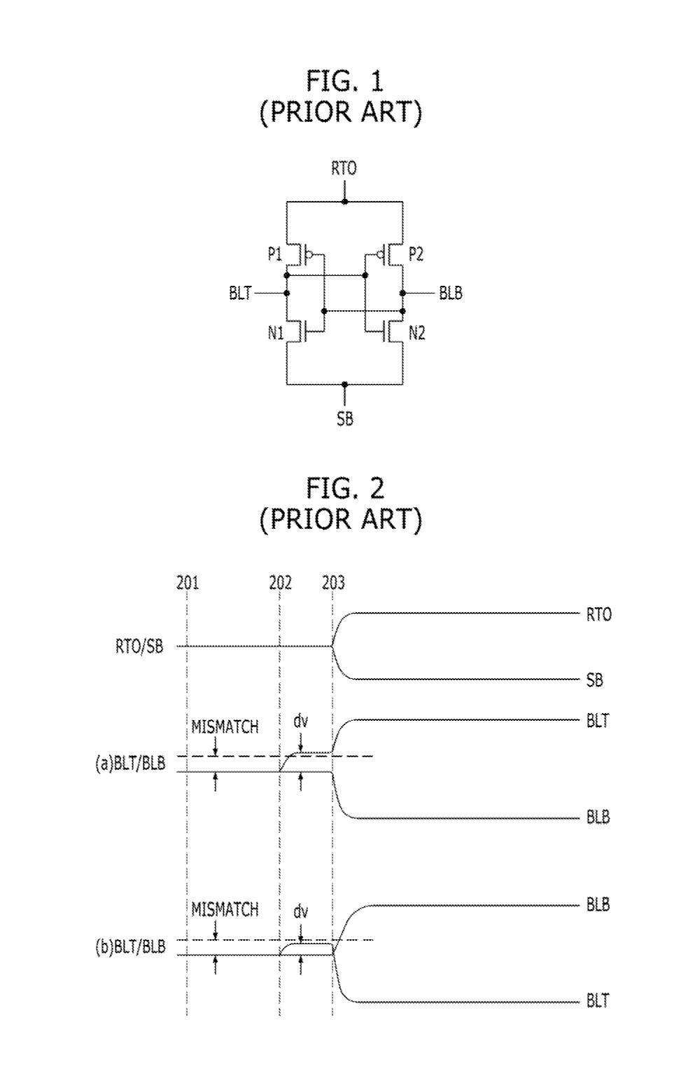

FIG. 5 is a diagram illustrating data sensing pass/fail areas of the conventional sense amplifier circuit (FIG. 1) and the sense amplifier circuit 320 according to the embodiment of the present invention.

Referring to FIG. 5, a vertical axis denotes a minimum dV (a voltage difference of a bit line pair) by which data sensing of the sense amplifier circuit is passed, and a horizontal axis denotes mismatch between pull-down transistors. Basically, when dV is increased and mismatch is small, the data sensing of the sense amplifier circuit is passed. When dV is reduced and mismatch becomes large, the data sensing of the sense amplifier circuit is failed.

A solid line ‘501’ indicates a boundary line of the pass/fail area of the sense amplifier circuit 320 according to the present invention and a dotted line ‘502’ indicates a boundary line of the pass/fail area of the conventional sense amplifier circuit (FIG. 1). Referring to FIG. 5, the pass area (an area above the solid line ‘501’)of the sense amplifier circuit 320 according to the embodiment of the present invention is larger than the pass area (an area above the dotted line ‘502’) of the conventional sense amplifier circuit (FIG. 1).

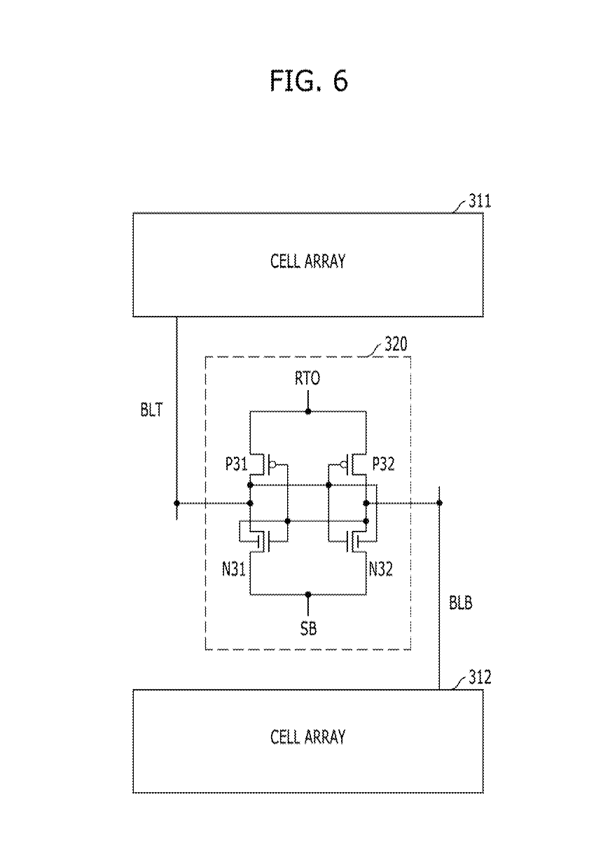

FIG. 6 is a configuration diagram of a memory device in accordance with another embodiment of the present invention.

Referring to FIG. 6, the memory device includes cell arrays 311 and 312, bit lines BLT and BLB, and a sense amplifier circuit 320.

FIG. 3 illustrates an embodiment of the present invention that is applied to a memory device having a folded bit line structure. FIG. 6 illustrates an embodiment of the present invention that is applied to a memory device having an open bit line structure. In the memory device having the folded bit line structure (FIG. 3), the bit line BLT and the bit bar line BLB are connected to the same cell array 310. However, in the memory device having the open bit line structure (FIG. 6), the bit line BLT and the bit bar line BLB are connected to the different arrays 311 and 312, respectively. Since the memory device of FIG. 6 is similar to the memory device of FIG. 3, except that the memory device of FIG. 6 has the open bit line structure, a detailed description thereof will be omitted.

While the present invention has been described with respect to the specific embodiments, it will be apparent to those skilled in the art that various changes and modifications may be made without departing from the spirit and scope of the invention as defined in the following claims.

Furthermore, in the exemplary embodiments, in which the sense amplifier circuit according to the present invention is used in order to sense/amplify data of bit lines, have been described. However, the sense amplifier circuit according to the present invention may also be used in order to amplify data in various integrated circuits in addition to the memory device.

What is claimed is:

1. A sense amplifier circuit comprising:
a first pull-up transistor configured to pull-up drive a data bar line in response to a voltage of a data line;
a first pull-down transistor configured to pull-down drive the data bar line in response to the voltage of the data line, and to receive the voltage of the data line through a back gate of the first pull-down transistor;
a second pull-up transistor configured to pull-up drive the data line in response to a voltage of the data bar line; and
a second pull-down transistor configured to pull-down drive the data line in response to the voltage of the data bar line, and to receive the voltage of the data bar line through a back gate of the second pull-down transistor.

2. The sense amplifier circuit of claim 1, wherein each of the first pull-down transistor and the second pull-down transistor includes a fully depleted silicon on insulator (FDSOI) NMOS transistor.

3. The sense amplifier circuit of claim 2, wherein each of the first pull-up transistor and the second pull-up transistor includes a PMOS transistor.

4. A memory device comprising:
one or more cell arrays,
a bit line and a bit bar line connected to the one or more cell arrays;
a first pull-up transistor configured to pull-up drive the bit bar line in response to a voltage of the bit line;
a first pull-down transistor configured to pull-down drive the bit bar line in response to the voltage of the bit line, and to receive the voltage of the bit line through a back gate of the first pull-down transistor;
a second pull-up transistor configured to pull-up drive the bit line in response to a voltage of the bit bar line; and
a second pull-down transistor configured to pull-down drive the bit line in response to the voltage of the bit bar line, and to receive the voltage of the bit bar line through a back gate of the second pull-down transistor.

5. The memory device of claim 4, wherein each of the first pull-down transistor and the second pull-down transistor includes a fully depleted silicon on insulator (FDSOI) NMOS transistor.

6. The memory device of claim 5, wherein each of the first pull-up transistor and the second pull-up transistor includes a PMOS transistor.

7. The memory device of claim 4 wherein the bit line and the bit bar line are connected to a substantially same cell array of the one or more cell arrays.

8. The memory device of claim 4, wherein the bit line and the bit bar line are connected to different cell arrays of the one or more cell arrays, respectively.
